(19) United States
(12) Patent Application Publication
(10) Pub. No.: US 2015/0097154 A1
(43) Pub. Date: Apr. 9, 2015

(54) SEMICONDUCTOR DEVICE HAVING SELECTOR AND RESISTIVE CHANGE DEVICE AND METHOD OF FORMING THE SAME

(71) Applicant: SAMSUNG ELECTRONICS CO., LTD., Suwon-Si (KR)

(72) Inventors: Kyung-Min KIM, Goyang-si (KR); Min-Kyu YANG, Hwaseong-si (KR); Gun-Hwan KIM, Hwaseong-si (KR)

(21) Appl. No.: 14/322,087

(22) Filed: Jul. 2, 2014

(30) Foreign Application Priority Data
Oct. 8, 2013 (KR) 10-2013-0119915

(51) Int. Cl. H01L 27/24

(52) U.S. Cl. CPC H01L 27/2409; H01L 27/2481
USPC 257/5

(57) ABSTRACT

At least one example embodiment discloses a semiconductor device including a first wiring on a substrate. A second wiring is on the first wiring. A first cell is between the first wiring and the second wiring. The first cell has a first selector and a first resistive change device. A third wiring is on the second wiring. A second cell is between the second wiring and the third wiring. The second cell has a second selector and a second resistive change device. The second selector has a different thickness from the first selector.

### CROSS-REFERENCE TO RELATED APPLICATION

This application claims priority under 35 U.S.C. §119 to Korean Patent Application No. 10-2013-0119915 filed on Oct. 8, 2013, the disclosure of which is hereby incorporated by reference in its entirety.

### BACKGROUND

1. Field

Example embodiments of inventive concepts relate to a semiconductor device having a selector and a resistive change device, and/or a method of forming the same.

2. Description of Related Art

Various techniques are being studied to implement the same electrical characteristics of selectors formed on different layers.

### SUMMARY

Some example embodiments of inventive concepts provide a semiconductor device capable of equally adjusting electrical characteristics of selectors formed on different layers and/or a method of forming the same.

The technical objectives of inventive concepts are not limited to the above disclosure; other objectives may become apparent to those of ordinary skill in the art based on the following descriptions.

At least one example embodiment of inventive concepts provides a semiconductor device. The semiconductor device includes first wirings on a substrate. Second wirings are on the first wirings. First cells are between the first and second wirings. The first cells have first selectors and first resistive change devices. Third wirings are on the second wirings. Second cells are between the second and third wirings. The second cells have second selectors and second resistive change devices. The second selectors have different thicknesses from the first selectors.

In some example embodiments, the second selectors may include a semiconductor pattern having a different impurity concentration from a semiconductor pattern of the first selectors.

In another example embodiment, the second selectors may be thinner than the first selectors.

In still another example embodiment, the first selectors may include first N-type and first P-type semiconductor patterns. The second selectors may include second N-type and second P-type semiconductor patterns. A first intrinsic semiconductor pattern may be formed between the first N-type and first P-type semiconductor patterns. A second intrinsic semiconductor pattern may be formed between the second N-type and second P-type semiconductor patterns.

In yet another example embodiment, the second intrinsic semiconductor pattern may be thinner than the first intrinsic semiconductor pattern. An impurity concentration of the first N-type semiconductor pattern may be higher than an impurity concentration of the second N-type semiconductor pattern. An impurity concentration of the first P-type semiconductor pattern may be higher than an impurity concentration of the second P-type semiconductor pattern.

In yet another example embodiment, the second intrinsic semiconductor pattern may be thicker than the first intrinsic semiconductor pattern. The first N-type semiconductor pattern may be thicker than the second N-type semiconductor pattern. The first P-type semiconductor pattern may be thicker than the second P-type semiconductor pattern. The impurity concentration of the first N-type semiconductor pattern may be higher than the impurity concentration of the second N-type semiconductor pattern. The impurity concentration of the first P-type semiconductor pattern may be higher than the impurity concentration of the second P-type semiconductor pattern.

In accordance with another example embodiment of inventive concepts, the semiconductor device includes first wirings on a substrate. Second wirings are formed on the first wirings. First cells are formed between the first and second wirings, and the first cells having first selectors and first resistive change devices are formed. Third wirings are formed on the second wirings. Second cells are formed between the second and third wirings, and the second cells having second selectors and second resistive change devices are formed. An impurity concentration of the second selectors may be different from that of the first selectors.

In some example embodiments, the first selectors may include first N-type and first P-type semiconductor patterns, and the second selectors may include second N-type and second P-type semiconductor patterns.

In another example embodiment, the impurity concentration of the first N-type semiconductor pattern may be higher than the impurity concentration of the second N-type semiconductor pattern.

In still another example embodiment, the impurity concentration of the first P-type semiconductor pattern may be higher than the impurity concentration of the second P-type semiconductor pattern.

In yet another example embodiment, the first intrinsic semiconductor pattern may be formed between the first N-type and first P-type semiconductor patterns. The second intrinsic semiconductor pattern may be formed between the second N-type and second P-type semiconductor patterns.

In accordance with another example embodiment of inventive concepts, the method includes forming first wirings on a substrate. First cells having first selectors and first resistive change devices are formed on the first wirings. Second wirings are formed on the first cells. Second cells having second selectors and second resistive change devices are formed on the second wirings. Third wirings are formed on the second cells. The second selectors have different thicknesses from the first selectors.

In some example embodiments, the second selectors may include a semiconductor pattern having a different impurity concentration from the first selectors.

In another example embodiment, the second selectors may be thinner than the first selectors.

In still another example embodiment, the first selectors may include first N-type and first P-type semiconductor patterns, and the second selectors may include second N-type and second P-type semiconductor patterns.

In yet another example embodiment, a first intrinsic semiconductor pattern may be formed between the first N-type and first P-type semiconductor patterns. A second intrinsic semiconductor pattern may be formed between the second N-type and second P-type semiconductor patterns. The second intrinsic semiconductor pattern may have a different thickness from the first intrinsic semiconductor pattern.

In yet another example embodiment, an impurity concentration of the first N-type semiconductor pattern may be higher than an impurity concentration of the second N-type semiconductor pattern.

In accordance with another example embodiment of inventive concepts, the method includes forming first wirings on a substrate. First cells having first selectors and first resistive change devices are formed on the first wirings. Second wirings are formed on the first cells. Second cells having second selectors and second resistive change devices are formed on the second wirings. Third wirings are formed on the second cells. An impurity concentration of the second selectors is different from that of the first selectors.

At least one example embodiment discloses a semiconductor device including a first plurality of wirings, a second plurality of wirings, a plurality of first cells between the first plurality of wirings and the second plurality of wirings, the first cells having first selectors and first resistive elements and a plurality of second cells on the second plurality of wirings, the second cells having second selectors and second resistive elements, a thickness of the second selectors being less than a thickness of the first selectors.

Details of other example embodiments are included in the detailed description and drawings.

### BRIEF DESCRIPTION OF THE DRAWINGS

The foregoing and other features and advantages of the inventive concepts will be apparent from the more particular description of example embodiments of inventive concepts, as illustrated in the accompanying drawings in which like reference characters refer to the same parts throughout the different views. The drawings are not necessarily to scale, emphasis instead being placed upon illustrating the principles of inventive concepts. In the drawings:

FIG. 1 is a perspective view of a semiconductor device in accordance with at least one example embodiment of inventive concepts;

FIG. 2 is an equivalent circuit diagram corresponding to a portion of FIG. 1;

FIG. 3 is a cross-sectional view of a semiconductor device in accordance with example embodiments of inventive concepts;

FIG. 4 is a graph showing a dopant profile in a PN diode;

FIGS. 5 to 12 are cross-sectional views of a semiconductor device in accordance with example embodiments of inventive concepts;

FIGS. 13 and 15 to 17 are cross-sectional views illustrating a method of fabricating a semiconductor device in accordance with example embodiments of inventive concepts;

FIG. 14 is an enlarged view showing a portion of FIG. 13 in detail;

FIG. 18 is a perspective view of an electronic apparatus in accordance with example embodiments of inventive concepts;

FIG. 19 is a system block diagram of an electronic apparatus in accordance with embodiments of the inventive concept;

FIGS. 20 to 22 are perspective views of electronic apparatuses in accordance with embodiments of the inventive concept; and

FIG. 23 is a system block diagram of electronic apparatuses in accordance with example embodiments of inventive concepts;

### DETAILED DESCRIPTION OF EXAMPLE EMBODIMENTS

Various example embodiments will now be described more fully with reference to the accompanying drawings in which some example embodiments are shown. Inventive concepts may, however, be embodied in different forms and should not be construed as limited to the embodiments set forth herein. Rather, example embodiments are provided so that this disclosure is thorough and complete and fully conveys the inventive concept to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of inventive concepts.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein is for the purpose of describing example embodiments only and is not intended to be limiting of inventive concepts. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of inventive concepts.

Unless otherwise defined, all terms (including technical and scientific terms) used herein have the same meaning as commonly understood by one of ordinary skill in the art to which inventive concepts belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

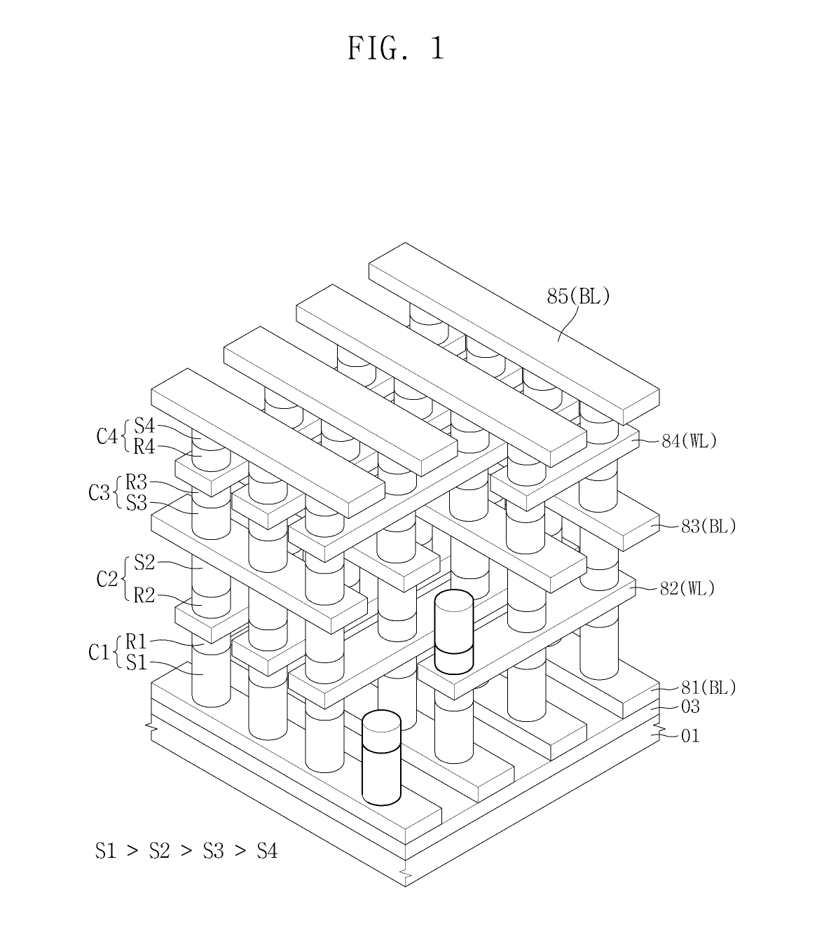

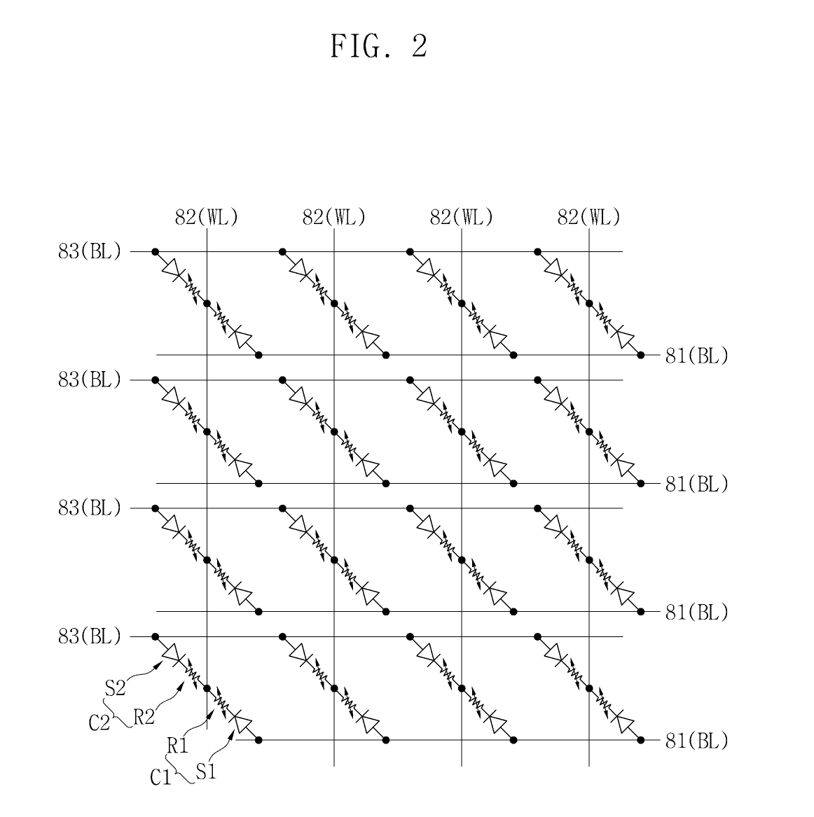

FIG. 1 is a perspective view of a semiconductor device in accordance with embodiments of the inventive concept, and FIG. 2 is an equivalent circuit diagram corresponding to a portion of FIG. 1. The semiconductor device may include a cell array region of a resistive random access memory (RRAM).

Referring to FIG. 1, a first insulating layer 03 may be formed on a substrate 01. First wirings 81 may be formed on the first insulating layer 03. First cells C1 may be formed on the first wirings 81. Each of the first cells C1 may include a first selector S1 and a first resistive change device R1. Second wirings 82 crossing over the first wirings 81 may be formed on the first cells C1. Second cells C2 may be formed on the second wirings 82. Each of the second cells C2 may include a second selector S2 and a second resistive change device R2. Third wirings 83 crossing over the second wirings 82 may be formed on the second cells C2. The second wirings 82 may serve as word lines, and the first wirings 81 and the third wirings 83 may serve as bit lines.

Third cells C3 may be formed on the third wirings 83. Each of the third cells C3 may include a third selector S3 and a third resistive change device R3. Fourth wirings 84 crossing over the third wirings 83 may be formed on the third cells C3. Fourth cells C4 may be formed on the fourth wirings 84. Each of the fourth cells C4 may include a fourth selector S4 and a fourth resistive change device R4. The fifth wirings 85 crossing over the fourth wirings 84 may be formed on the fourth cells C4. The fourth wirings 84 may serve as word lines, and the fifth wirings 85 may serve as bit lines.

The first selector S1, the second selector S2, the third selector S3, and the fourth selector S4 may be formed to have different thicknesses in consideration of a thermal budget. For example, the second selector S2 may be thinner than the first selector S1, the third selector S3 may be thinner than the second selector S2, and the fourth selector S4 may be thinner than the third selector S3. The first selector S1, the second selector S2, the third selector S3, and the fourth selector S4 may be formed to have different impurity concentrations in consideration of a thermal budget. The first selector S1, the second selector S2, the third selector S3, and the fourth selector S4 may have substantially the same electrical characteristics. The first selector S1, the second selector S2, the third selector S3, and the fourth selector S4 may have substantially the same operating current.

Referring to FIG. 2, the first wirings 81 may be referred to as lower bit lines 81. The lower bit lines 81 may be parallel to each other. The second wirings 82 may be referred to as word lines 82. The word lines 82 may cross over the lower bit lines 81. The word lines 82 may be parallel to each other. The third wirings 83 may be referred to as upper bit lines 83. The upper bit lines 83 may cross over the word lines 82. The upper bit lines 83 may be parallel to each other. The first cells C1 may be formed at crossing points between the lower bit lines 81 and the word lines 82. The first cells C1 may be referred to as lower cells C1. The lower cells C1 may include the first selectors S1 and the first resistive change devices R1. The first selectors S1 may be referred to as lower selectors S1. The first resistive change devices R1 may be referred to as lower resistive change devices R1. The second cells C2 may be formed at crossing points between the word lines 82 and the upper bit lines 83. The second cells C2 may be referred to as upper cells C2. The upper cells C2 may include the second selectors S2 and the second resistive change devices R2. The second selectors S2 may be referred to as upper selectors S2. The second resistive change devices R2 may be referred to as upper resistive change devices R2.

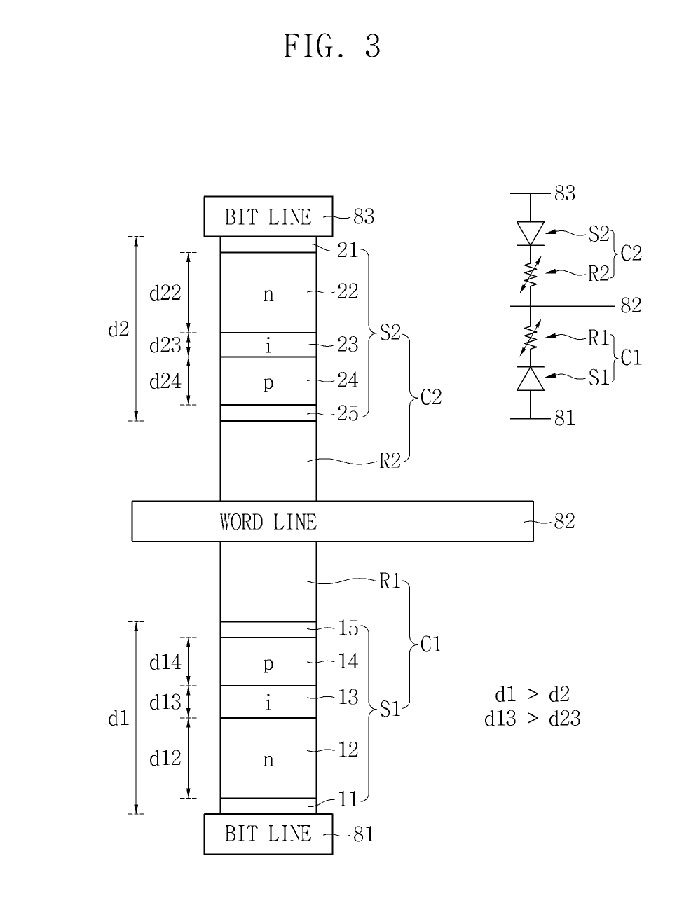

FIG. 3 is a cross-sectional view of a semiconductor device in accordance with at least one example embodiment of inventive concepts.

Referring to FIG. 3, a first lower electrode 11, a first N-type semiconductor pattern 12, a first intrinsic semiconductor pattern 13, a first P-type semiconductor pattern 14, and a first upper electrode 15 may be sequentially stacked on the lower bit lines 81. The first lower electrode 11, the first N-type semiconductor pattern 12, the first intrinsic semiconductor pattern 13, the first P-type semiconductor pattern 14, and the first upper electrode 15 may configure the lower selectors S1. The lower resistive change devices R1 may be formed on the lower selectors S1. The word lines 82 may be formed on the lower resistive change device R1. The lower selectors S1 and the lower resistive change devices R1 may configure the lower cells C1.

The upper resistive change devices R2 may be formed on the word lines 82. A second lower electrode 25, a second P-type semiconductor pattern 24, a second intrinsic semiconductor pattern 23, a second N-type semiconductor pattern 22, and a second upper electrode 21 may be sequentially stacked on the upper resistive change device R2. The second lower electrode 25, the second P-type semiconductor pattern 24, the second intrinsic semiconductor pattern 23, the second N-type semiconductor pattern 22, and the second upper electrode 21 may configure the upper selectors S2. The upper bit line 83 may be formed on the upper selectors S2. The upper resistive change devices R2 and the upper selectors S2 may configure the upper cell C2. The first lower electrode 11, the first upper electrode 15, the second lower electrode 25, and the second upper electrode 21 may include Ti, TiN, TiSi, TiSiN, TiAlN, TiCN, Ta, TaN, TaSi, TaSiN, TaAlN, TaCN, W, WN, WSi, NiSi, CoSi, Ru, Ir, Pt, or a combination thereof. The first lower electrode 11, the first upper electrode 15, the second lower electrode 25, and the second upper electrode 21 may include different materials. The first lower electrode 11, the first upper electrode 15, the second lower electrode 25, and the second upper electrode 21 may be selectively omitted.

The first and second N-type semiconductor patterns 12 and 22 may be semiconductor films having N-type impurities. For example, the first and second N-type semiconductor patterns 12 and 22 may be silicon films having P, As, or a combination thereof. The first and second P-type semiconductor patterns 14 and 24 may be semiconductor films having P-type impurities. For example, the first and second P-type semiconductor patterns 14 and 24 may be silicon films having B, BF, or a combination thereof.

The first and second intrinsic semiconductor patterns 13 and 23 may be semiconductor films having a first amount of N-type and P-type impurities or less, or having no impurities. For example, the first and second intrinsic semiconductor patterns 13 and 23 may be silicon films having a first amount of N-type and P-type impurities or less, or having no impurities. The first intrinsic semiconductor pattern 13 may be located between the first N-type semiconductor patterns 12 and the first P-type semiconductor patterns 14. The first intrinsic semiconductor pattern 13 may be in direct contact with the first N-type semiconductor patterns 12 and the first P-type semiconductor patterns 14. The second intrinsic semiconductor pattern 23 may be located between the second P-type semiconductor patterns 24 and the second N-type semiconductor patterns 22. The second intrinsic semiconductor pattern 23 may be in direct contact with the second P-type semiconductor patterns 24 and the second N-type semiconductor patterns 22. The lower selectors S1 and the upper selectors S2 may be regarded as PN diodes.

The lower selector S1 may have a first thickness d1. The upper selector S2 may have a second thickness d2. The first N-type semiconductor pattern 12 may have a third thickness d12. The first intrinsic semiconductor pattern 13 may have a fourth thickness d13. The first P-type semiconductor pattern 14 may have a fifth thickness d14. The second P-type semiconductor pattern 24 may have a sixth thickness d24. The second intrinsic semiconductor pattern 23 may have a seventh thickness d23. The second N-type semiconductor pattern 22 may have an eighth thickness d22.

The lower selector S1 and the upper selector S2 may have different thicknesses in consideration of a thermal budget. For example, the second thickness d2 of the upper selector S2 may be thinner than the first thickness d1 of the lower selector S1 (d1>d2). The seventh thickness d23 of the second intrinsic semiconductor pattern 23 may be thinner than the fourth thickness d13 of the first intrinsic semiconductor pattern 13 (d13>d23).

In another example embodiment, the lower and upper selectors S1 and S2 may be formed to have different impurity concentrations in consideration of a thermal budget. The lower and upper selectors S1 and S2 may be configured to have various thicknesses and combinations of various impurity concentrations. The lower and upper selectors S1 and S2 may have substantially the same electrical characteristics. The lower and upper selectors S1 and S2 may have substantially the same operating current.

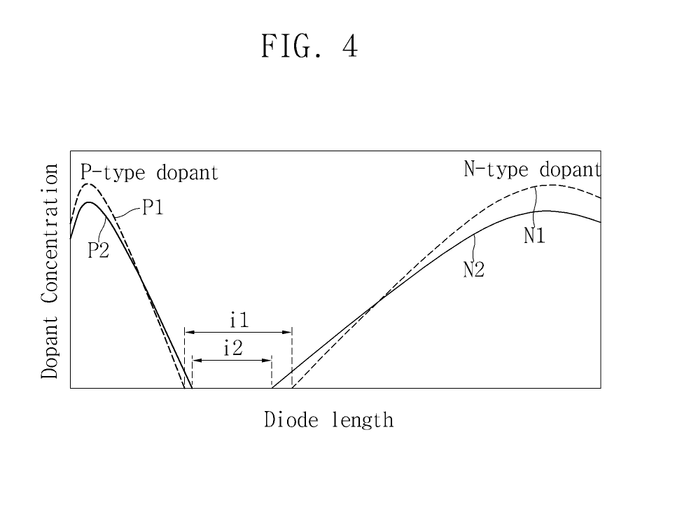

FIG. 4 is a graph showing a dopant profile in a PN diode. A horizontal axis of FIG. 4 indicates a length of a diode, and a vertical axis of FIG. 4 indicates a dopant concentration.

Referring to FIG. 4, first N-type and first P-type regions N1 and P1 may be formed in an operation of forming a diode. A first intrinsic region i1 may be located between the first N-type and first P-type regions N1 and P1. Second N-type and second P-type regions N2 and P2 may be formed by diffusion of a dopant in the diode that may be exposed in a subsequent heat treatment process. A second intrinsic region i2 may be located between the second N-type and second P-type regions N2 and P2. The second intrinsic region i2 may be narrower than the first intrinsic region i1. Electrical characteristics of the diode may be determined by the width of the second intrinsic region i2, and dopant concentrations of the second N-type and second P-type regions N2 and P2.

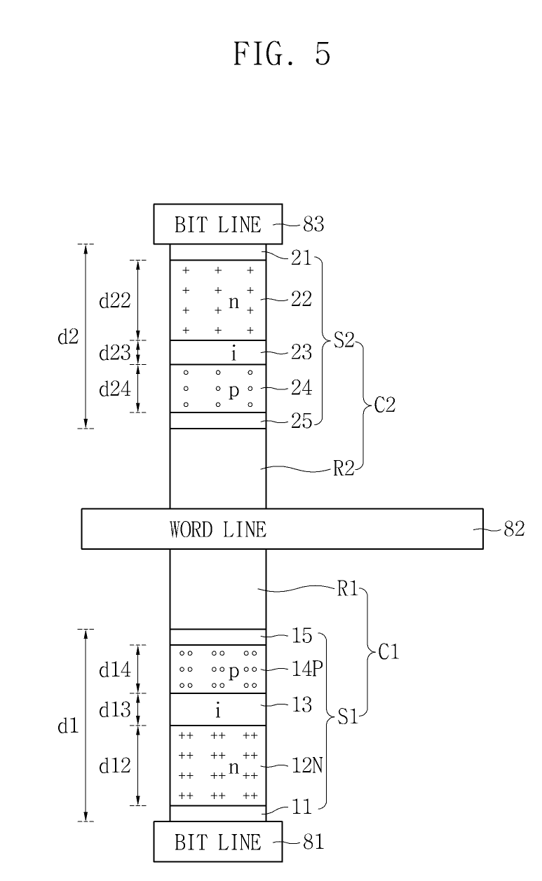

FIGS. 5 to 12 are cross-sectional views of a semiconductor device in accordance with example embodiments of inventive concepts.

Referring to FIG. 5, first and second N-type semiconductor patterns 12N and 22 may be semiconductor films having N-type impurities. A dopant concentration in the first N-type semiconductor pattern 12N may be higher than that of the second N-type semiconductor pattern 22. First and second P-type semiconductor patterns 14P and 24 may be semiconductor films having P-type impurities. A dopant concentration in the first P-type semiconductor pattern 14P may be higher than that of the second P-type semiconductor pattern 24.

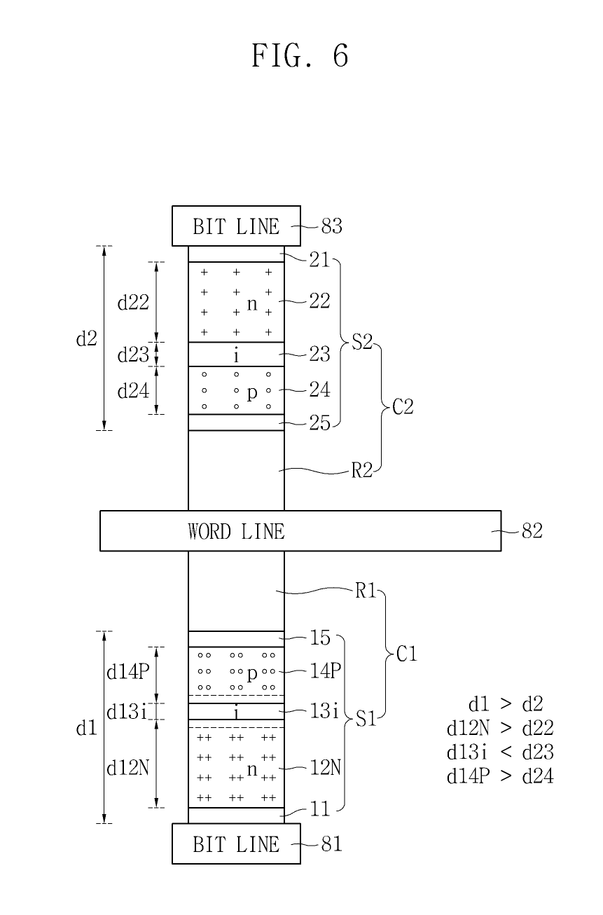

Referring to FIG. 6, a second thickness d2 of an upper selector S2 may be thinner than a first thickness d1 of a lower selector S1 (d1>d2). A seventh thickness d23 of a second intrinsic semiconductor pattern 23 may be thicker than a fourth thickness d13i of a first intrinsic semiconductor pattern 13 (d13i<d23). A third thickness d12N of the first P-type semiconductor pattern 12N may be thicker than an eighth thickness d22 of the second N-type semiconductor pattern 22 (d12N>d22). A fifth thickness d14P of the first P-type semiconductor pattern 14P may be thicker than a sixth thickness d24 of the second P-type semiconductor pattern 24 (d14P>d24). A dopant concentration in the first N-type semiconductor pattern 12N may be higher than that of the second N-type semiconductor pattern 22. A dopant concentration in the first P-type semiconductor pattern 14P may be higher than that of the second P-type semiconductor pattern 24.

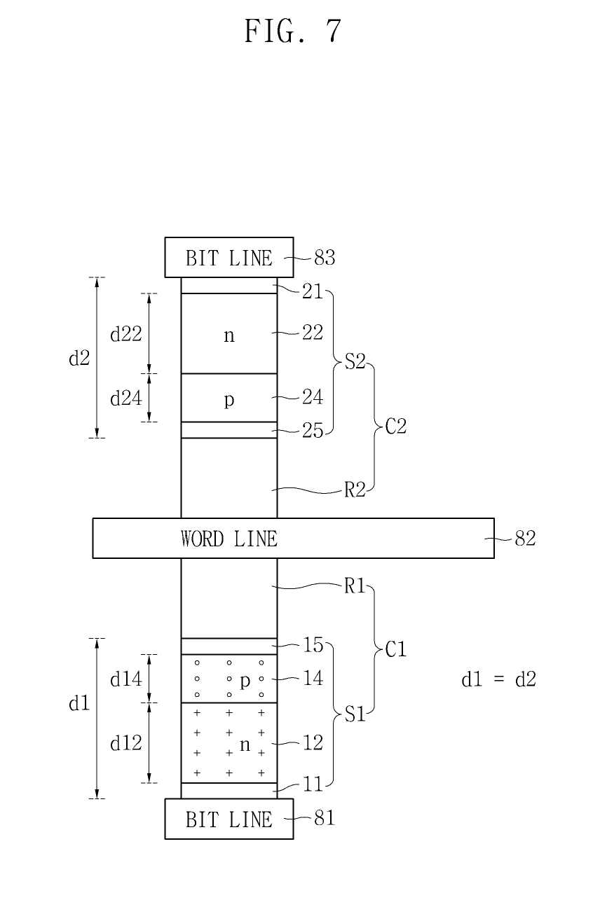

Referring to FIG. 7, the first N-type semiconductor pattern 12 may be in direct contact with the first P-type semiconductor pattern 14. The second P-type semiconductor pattern 24 may be in direct contact with the second N-type semiconductor pattern 22. A dopant concentration in the first N-type semiconductor pattern 12 may be higher than that of the second N-type semiconductor pattern 22. A dopant concentration in the first P-type semiconductor pattern 14 may be higher than that of the second P-type semiconductor pattern. The first thickness d1 of the lower selector S1 may be substantially the same as the second thickness d2 of the upper selector S2 (d1=d2).

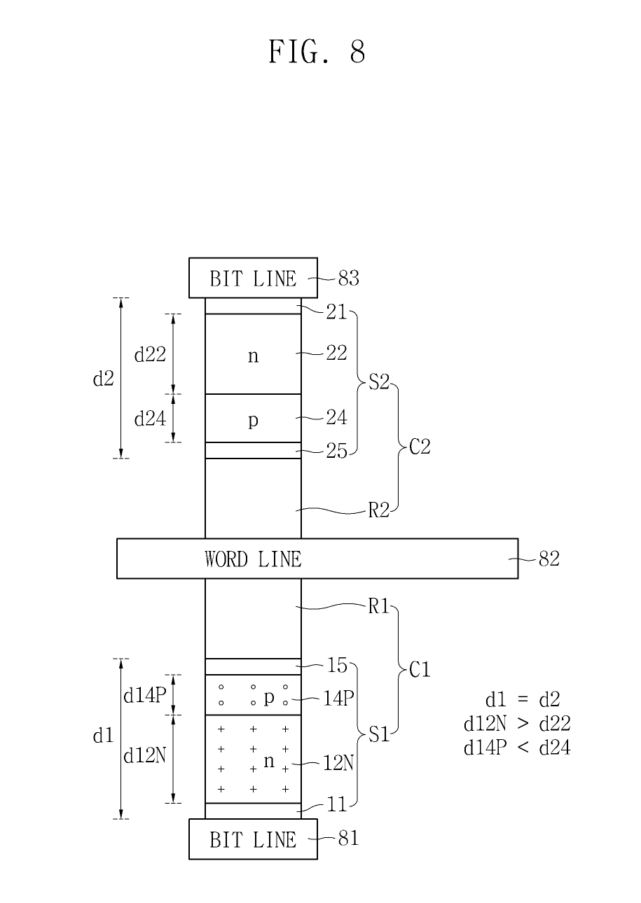

Referring to FIG. 8, the third thickness d12N of the first N-type semiconductor pattern 12N may be thicker than the eighth thickness d22 of the second N-type semiconductor pattern 22 (d12N>d22). The fifth thickness d14P of the first P-type semiconductor pattern 14P may be thinner than the sixth thickness d24 of the second P-type semiconductor pattern 24 (d14P<d24). A dopant concentration in the first N-type semiconductor pattern 12N may be higher than that of the second N-type semiconductor pattern 22. A dopant concentration in the first P-type semiconductor pattern 14P may be higher than that of the second P-type semiconductor pattern 24.

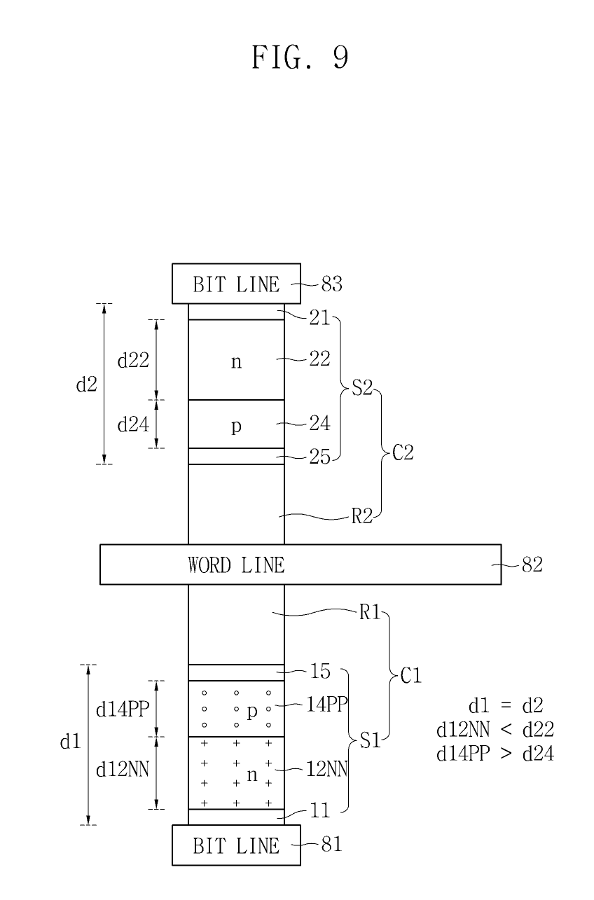

Referring to FIG. 9, a third thickness d12NN of a first N-type semiconductor pattern 12NN may be thinner than the eighth thickness d22 of the second N-type semiconductor pattern 22 (d12NN<d22). A fifth thickness d14PP of a first P-type semiconductor pattern 14PP may be thicker than the sixth thickness d24 of the second P-type semiconductor pattern 24 (d14PP>d24).

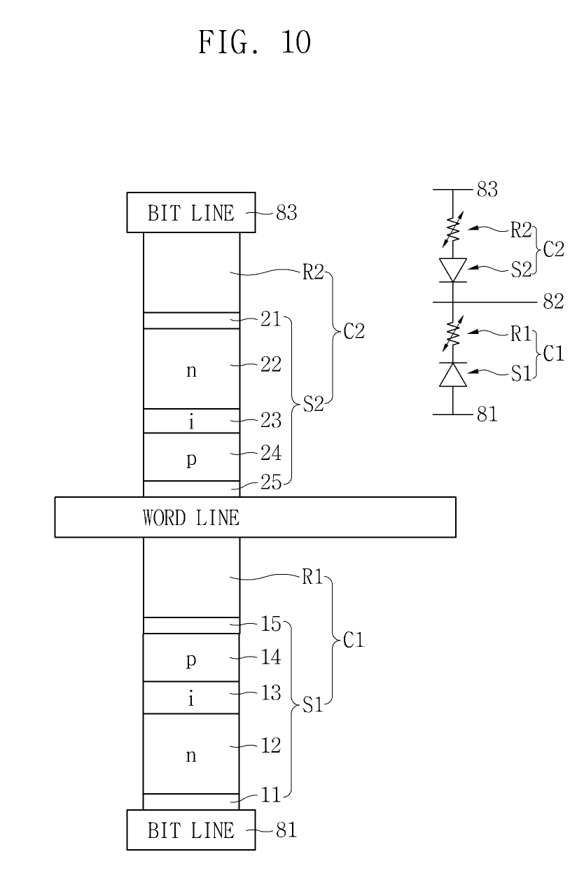

Referring to FIG. 10, the lower selectors S1, the lower resistive change devices R1, the upper selectors S2, and the upper resistive change devices R2 may have various dispositions. For example, the lower selectors S1 may be formed on the lower bit lines 81. The lower resistive change devices R1 may be formed on the lower selectors S1. The word lines 82 may be formed on the lower resistive change devices R1. The upper selectors S2 may be formed on the word lines 82. The upper resistive change devices R2 may be formed on the upper selectors S2. The upper bit lines 83 may be formed on the upper resistive change devices R2.

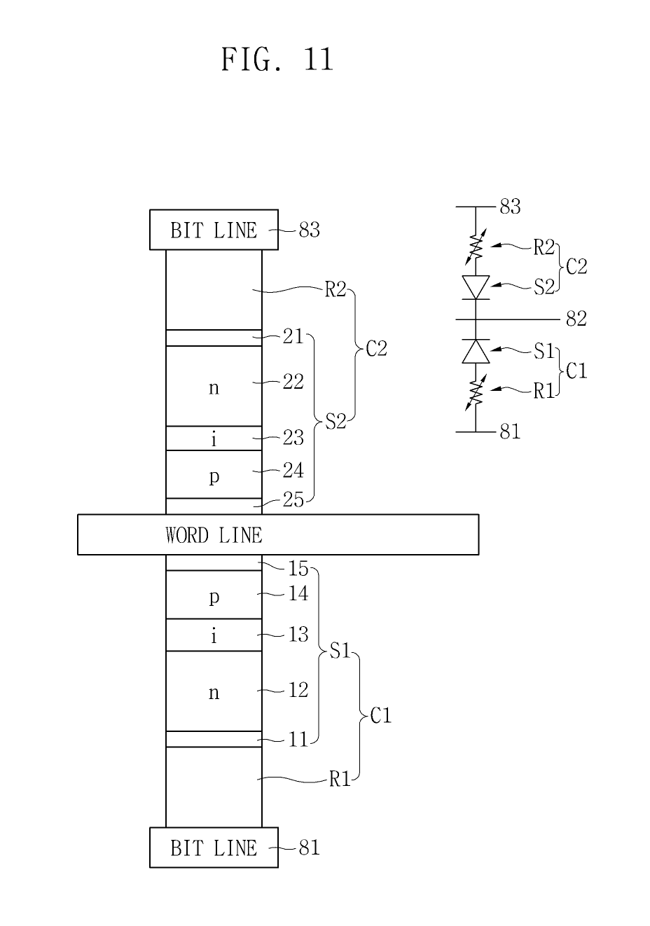

Referring to FIG. 11, the lower resistive change devices R1 may be formed on the lower bit lines 81. The lower selectors S1 may be formed on the lower resistive change devices R1. The word lines 82 may be formed on the lower selectors S1. The upper selectors S2 may be formed on the word lines 82. The upper resistive change devices R2 may be formed on the upper selectors S2. The upper bit lines 83 may be formed on the upper resistive change devices R2.

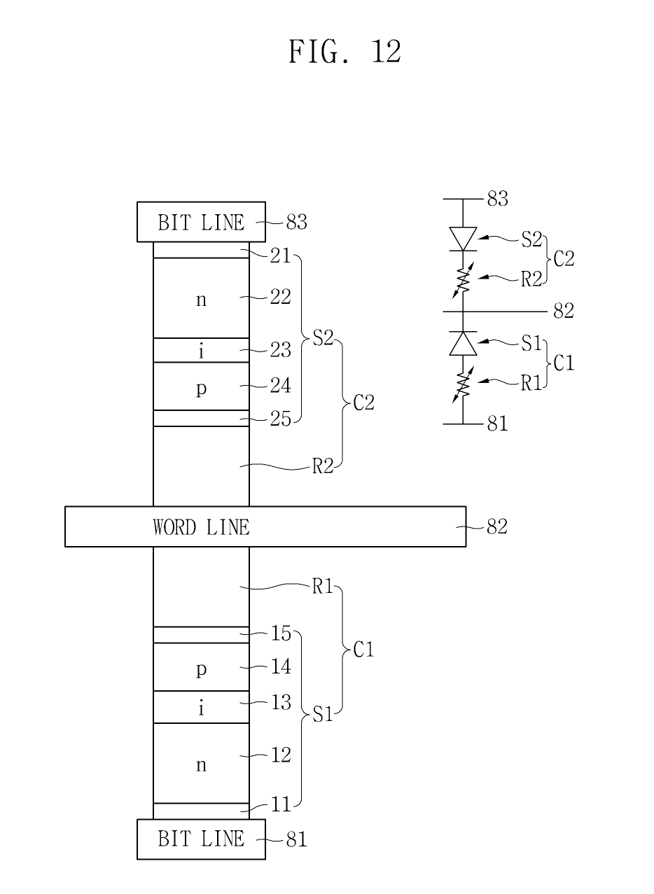

Referring to FIG. 12, the lower selectors S1 may be formed on the lower bit lines 81. The lower resistive change devices R1 may be formed on the lower selectors S1. The word lines 82 may be formed on the lower resistive change devices R1. The upper resistive change devices R2 may be formed on the word lines 82. The upper selectors S2 may be formed on the upper resistive change devices R2. The upper bit lines 83 may be formed on the upper selectors S2.

FIGS. 13 and 15 to 17 are cross-sectional views of a method of fabricating a semiconductor device in accordance with example embodiments of inventive concepts, and FIG. 14 is an enlarged view showing a portion of FIG. 13 in detail.

Referring to FIGS. 1 and 13, a first insulating layer 03 may be formed on a substrate 01. A second insulating layer 05 and first wirings 81 may be formed on the first insulating layer 03. A third insulating layer 72 and first cells C1 may be formed on the second insulating layer 05 and the first wirings 81. Second wirings 82 connected to the first cells C1 may be formed on the third insulating layer 72. Each of the first cells C1 may include one of a first selector S1 and a first resistive change device R1. The first selector S1 may have a similar configuration to that described with reference to FIGS. 3 to 17.

The substrate 01 may be a semiconductor substrate such as a silicon wafer or a silicon-on-insulator (SOI) wafer. The first insulating layer 03 may include silicon oxide, silicon nitride, silicon oxynitride, or a combination thereof. Active/passive devices such as various types of transistors, capacitors, resistors, inductors, and interconnections may be formed in the substrate 01 and the first insulating layer 03, but description thereof will be omitted for the sake of brevity.

The second insulating layer 05 may be filled among the first wirings 81. The second insulating layer 05 may include silicon oxide, silicon nitride, silicon oxynitride, or a combination thereof. The first wirings 81 may be parallel to each other. The first wirings 81 may include Ti, TiN, TiSi, TiSiN, TiAlN, TiCN, Ta, TaN, TaSi, TaSiN, TaAlN, TaCN, W, WN, WSi, NiSi, CoSi, Ru, Ir, Pt, Cu, Al, or a combination thereof. The third insulating layer 72 may cover the second insulating layer 05 and the first wirings 81. The third insulating layer 72 may include silicon oxide, silicon nitride, silicon oxynitride, or a combination thereof.

Each of the first cells C1 may be connected to one selected from the first wirings 81 through the third insulating layer 72. The first selector S1 may be formed as described with reference to FIGS. 3 to 17. The first resistive change device R1 may be formed on the first selectors S1. The second wirings 82 may be in contact with the first resistive change device R1. The second wirings 82 may include Ti, TiN, TiSi, TiSiN, TiAlN, TiCN, Ta, TaN, TaSi, TaSiN, TaAlN, TaCN, W, WN, WSi, NiSi, CoSi, Ru, Ir, Pt, Cu, Al, or a combination thereof.

Referring to FIGS. 1 and 14, the first resistive change devices R1 may include first to sixth layers 61, 62, 63, 64, 65, and 66 which are sequentially stacked. The first layer 61 may be a first electrode 61. The first electrode 61 may include Ir, Pt, Ni, Ru, Pd, Co, or a combination thereof. The second layer 62 may be SiO. The third layer 63 may be AlO. The fourth layer 64 may be TaO. The fifth layer 65 may be A10. The sixth layer 66 may be a second electrode 66. The second electrode 66 may include Ir, Pt, Ni, Ru, Pd, Co, or a combination thereof. The third and fifth layers 63 and 65 may include the same materials. The third and fifth layers 63 and 65 may have substantially the same thickness. The second layer 62 may be thinner than the third layer 63. The second layer 62 may be thinner than the fifth layer 65. The fourth layer 64 may be thicker than the third layer 63. The fourth layer 64 may be thicker than the fifth layer 65. The first electrode 61 may be omitted. The second electrode 66 may be omitted.

In other embodiments, the first resistive change devices R1 may include HfO, A10, SiO, TiO, TaO, ZrO, NiO, CoO, ZnO, CuO, CrO, FeO, NbO, or a combination thereof. The first resistive change devices R1 may include a phase change material layer, a polymer layer, or a ferroelectric layer.

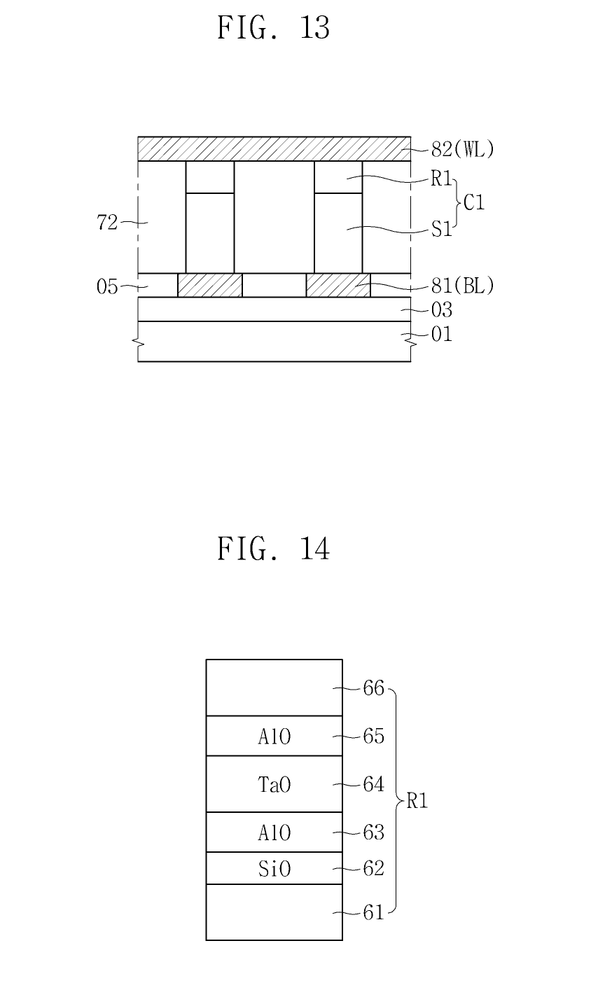

Referring to FIGS. 1 and 15, a fourth insulating layer 74 and second cells C2 may be formed on the third insulating layer 72 and the second wirings 82. Third wirings 83 and a fifth insulating layer 75 may be formed on the fourth insulating layer 74. The third wirings 83 may be connected to the second cells C2. Each of the second cells C2 may include a second selector S2 and a second resistive change device R2. The second selector S2 may have a similar configuration to that described with reference to FIGS. 3 to 12.

The fourth insulating layer 74 may cover the third insulating layer 72 and the second wirings 82. The fourth insulating layer 74 may include silicon oxide, silicon nitride, silicon oxynitride, or a combination thereof. Each of the second cells C2 may be connected to one selected from the second wirings 82 through the fourth insulating layer 74. The second resistive change device R2 may be in direct contact with one selected from the second wirings 82. The second resistive change devices R2 may have a similar configuration to the first resistive change device R1. The second selector S2 may be formed on the second resistive change device R2. The second selector S2 may be formed as described with reference to FIGS. 3 to 12.

The fifth insulating layer 75 may be filled among the third wirings 83. The fifth insulating layer 75 may include silicon oxide, silicon nitride, silicon oxynitride, or a combination thereof. The third wirings 83 may be in contact with the second selector S2. The third wirings 83 may include Ti, TiN, TiSi, TiSiN, TiAlN, TiCN, Ta, TaN, TaSi, TaSiN, TaAlN, TaCN, W, WN, WSi, NiSi, CoSi, Ru, Ir, Pt, Cu, Al, or a combination thereof.

While forming the fourth insulating layer 74, the second cells C2, the third wirings 83, and the fifth insulating layer 75, the first selector 51 may be exposed to a high-temperature heat treatment process.

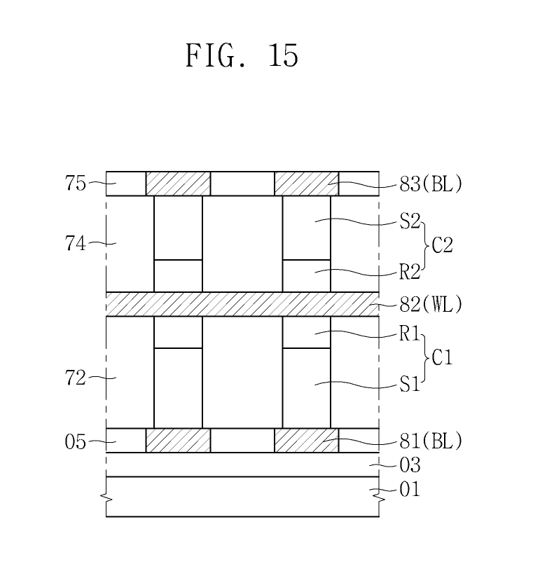

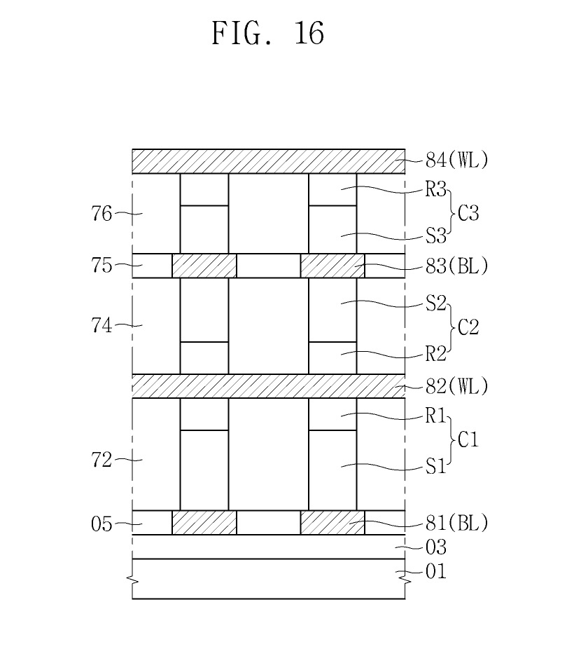

Referring to FIGS. 1 and 16, a sixth insulating layer 76 and third cells C3 may be formed on the fifth insulating layer 75 and the third wirings 83. Fourth wirings 84 connected to the third cells C3 may be formed on the sixth insulating layer 76. Each of the third cells C3 may include a third selector S3 and a third resistive change device R3.

The sixth insulating layer 76 may cover the fifth insulating layer 75 and the third wirings 83. The sixth insulating layer 76 may include silicon oxide, silicon nitride, silicon oxynitride, or a combination thereof. Each of the third cells C3 may be connected to one selected from the third wirings 83 through the sixth insulating layer 76. The third selector S3 may be formed as described with reference to FIGS. 3 to 17. The third resistive change device R3 may be formed on the third selector S3. The third resistive change device R3 may have a similar configuration to the first resistive change device R1. The fourth wirings 84 may be in contact with the third resistive change device R3. The fourth wirings 84 may include Ti, TiN, TiSi, TiSiN, TiAlN, TiCN, Ta, TaN, TaSi, TaSiN, TaAlN, TaCN, W, WN, WSi, NiSi, CoSi, Ru, Ir, Pt, Cu, Al, or a combination thereof.

While forming the sixth insulating layer 76, the third cells C3, and the fourth wirings 84, the first selector S1 may be repeatedly exposed to a high-temperature heat treatment process. While forming the sixth insulating layer 76, the third cells C3, and the fourth wirings 84, the second selector S2 may be exposed to a high-temperature heat treatment process.

Referring to FIGS. 1 and 17, a seventh insulating layer 77 and fourth cells C4 may be formed on the sixth insulating layer 76 and the fourth wirings 84. Fifth wirings 85 and an eighth insulating layer 78 may be formed on the seventh insulating layer 77. The fifth wirings 85 may be in contact with the fourth cells C4. Each of the fourth cells C4 may include a fourth selector S4 and a fourth resistive change device R4. The fourth selector S4 may have a similar configuration to that described with reference to FIGS. 3 to 12.

The seventh insulating layer 77 may cover the sixth insulating layer 76 and the fourth wirings 84. The seventh insulating layer 77 may include silicon oxide, silicon nitride, silicon oxynitride, or a combination thereof. Each of the fourth cells C4 may be connected to one selected from the fourth wirings 84 through the seventh insulating layer 77. The fourth resistive change device R4 may be in direct contact with one selected from the fourth wirings 84. The fourth resistive change device R4 may have a similar configuration to the first resistive change device R1. The fourth selector S4 may be formed on the fourth resistive change device R4. The fourth selector S4 may be formed as described with reference to FIGS. 3 to 12.

The eighth insulating layer 78 may be filled among the fifth wirings 85. The eighth insulating layer 78 may include silicon oxide, silicon nitride, silicon oxynitride, or a combination thereof. The fifth wirings 85 may be in contact with the fourth selector S4.

The fifth wirings 85 may include Ti, TiN, TiSi, TiSiN, TiAlN, TiCN, Ta, TaN, TaSi, TaSiN, TaAlN, TaCN, W, WN, WSi, NiSi, CoSi, Ru, Ir, Pt, Cu, Al, or a combination thereof.

While forming the seventh insulating layer 77, the fourth cells C4, the fifth wirings 85, and the eighth insulating layer 78, the first and second selectors S1 and S2 may be repeatedly exposed to a high-temperature heat treatment process. While forming the seventh insulating layer 77, the fourth cells C4, the fifth wirings 85, and the eighth insulating layer 78, the third selector S3 may be exposed to a high-temperature heat treatment process.

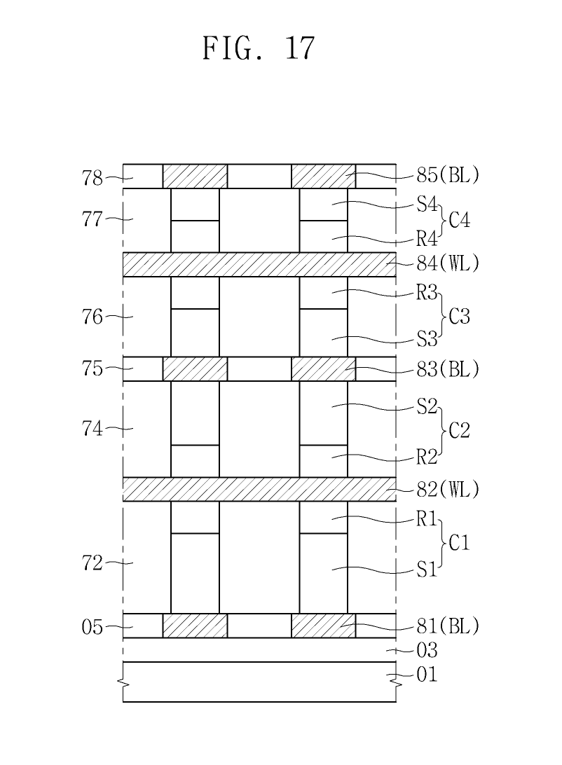

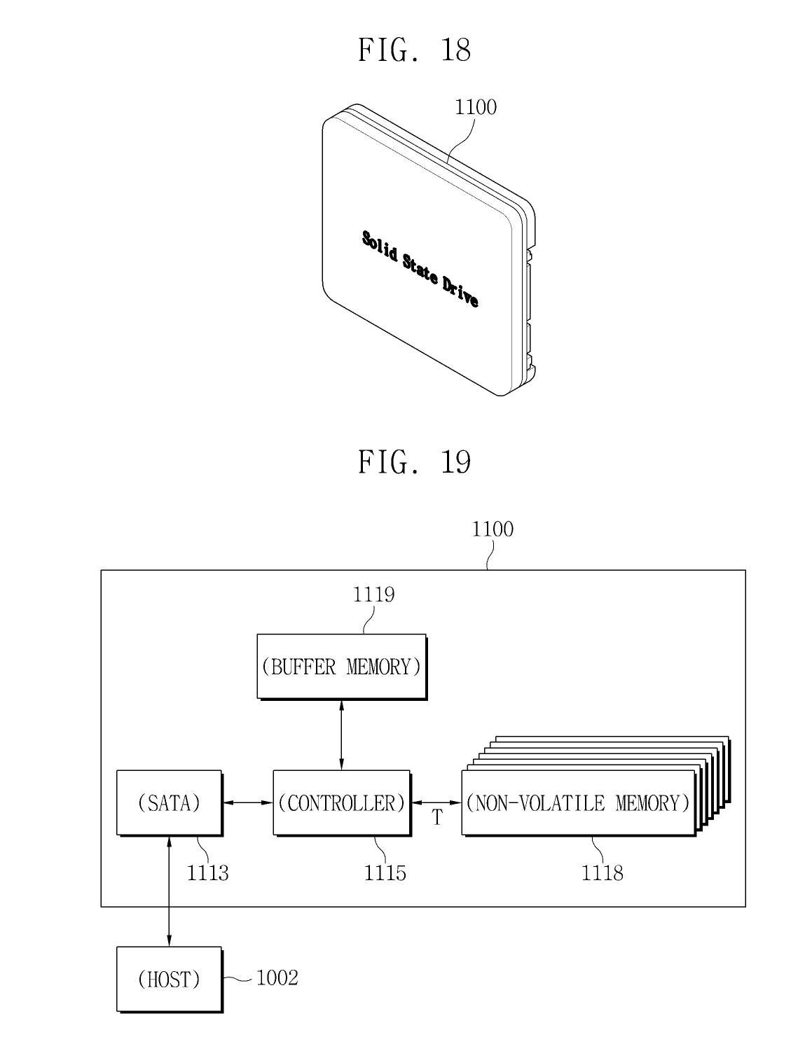

FIG. 18 is a perspective view of an electronic apparatus in accordance with another example embodiment of inventive concepts, and FIG. 19 is a system block diagram of an electronic apparatus in accordance with example embodiments of inventive concepts. The electronic apparatus may be a data storage device such as a solid state drive (SSD) 1100.

Referring to FIGS. 18 and 19, the SSD 1100 may include an interface 1113, a controller 1115, a non-volatile memory 1118, and a buffer memory 1119. The SSD 1100 is an apparatus configured to store data using a semiconductor device. The SSD 1100 may have a faster speed, less mechanical delay, failure, heat and noise, and may be smaller and lighter than a hard disk drive (HDD). The SSD 1100 may be used for a laptop, a notebook PC, a desktop PC, an MP3 player, or a portable storage apparatus.

The controller 1115 may be located adjacent to the interface 1113 and electrically connected to the interface 1113. The controller 1115 may be a microprocessor including a memory controller and a buffer controller. The non-volatile memory 1118 may be located adjacent to the controller 1115 and electrically connected to the controller 1115. A data storage capacity of the SSD 1100 may be similar to the non-volatile memory 1118. The buffer memory 1119 may be located adjacent to the controller 1115 and electrically connected to the controller 1115.

The interface 1113 may be connected to a host 1002 and serve to transmit electrical signals such as data. For example, the interface 1113 may be an apparatus according to a standard such as SATA, IDE, SCSI, and/or a combination thereof. The non-volatile memory 1118 may be in contact with the interface 1113 through the controller 1115. The non-volatile memory 1118 may serve to store data received from the interface 1113. Even when power supply of the SSD 1100 is cut off, the stored data in the non-volatile memory 1118 may be retained.

The buffer memory 1119 may include a volatile memory. The volatile memory may be a dynamic random access memory (DRAM), and/or a static random access memory (SRAM). The buffer memory 1119 may have a relatively faster operating speed than the non-volatile memory 1118.

A data processing speed of the interface 1113 may be faster than an operating speed of the non-volatile memory 1118. Herein, the buffer memory 1119 may serve to temporarily store data. Data received through the interface 1113 may be temporarily stored in the buff memory 1119 through the controller 1115, and permanently stored in the non-volatile memory 1118 at a data writing speed of the non-volatile memory. Furthermore, frequently used data among stored data in the non-volatile memory 1118 may be pre-read and may be stored temporarily in the buffer memory 1119. That is, the buffer memory 1119 may serve to increase an available operating speed of the solid state drive 1100 and decrease an error occurrence rate.

The non-volatile memory 1118 may have a similar configuration to that described with reference to FIGS. 1 to 17.

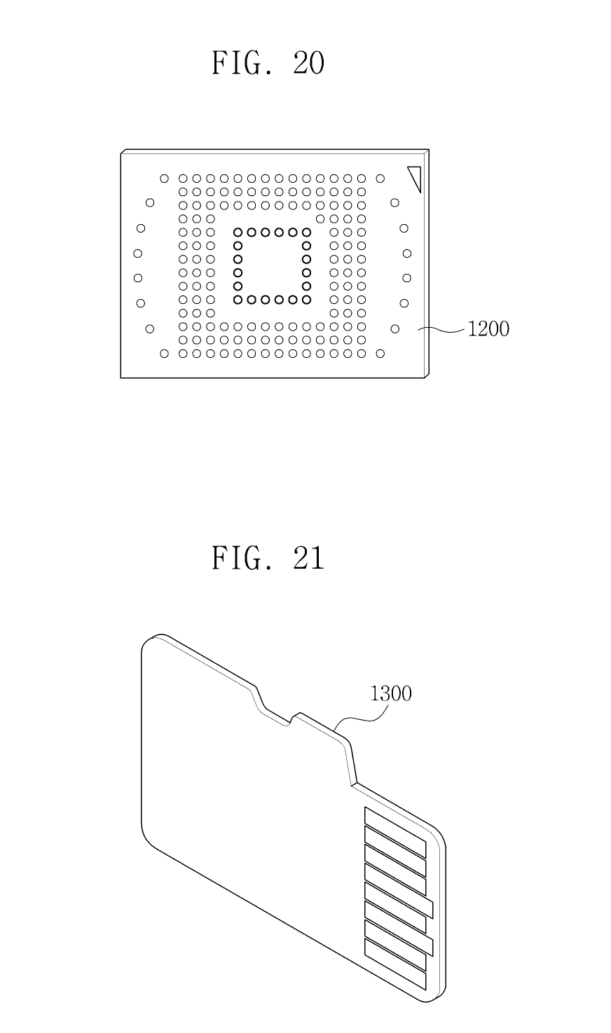

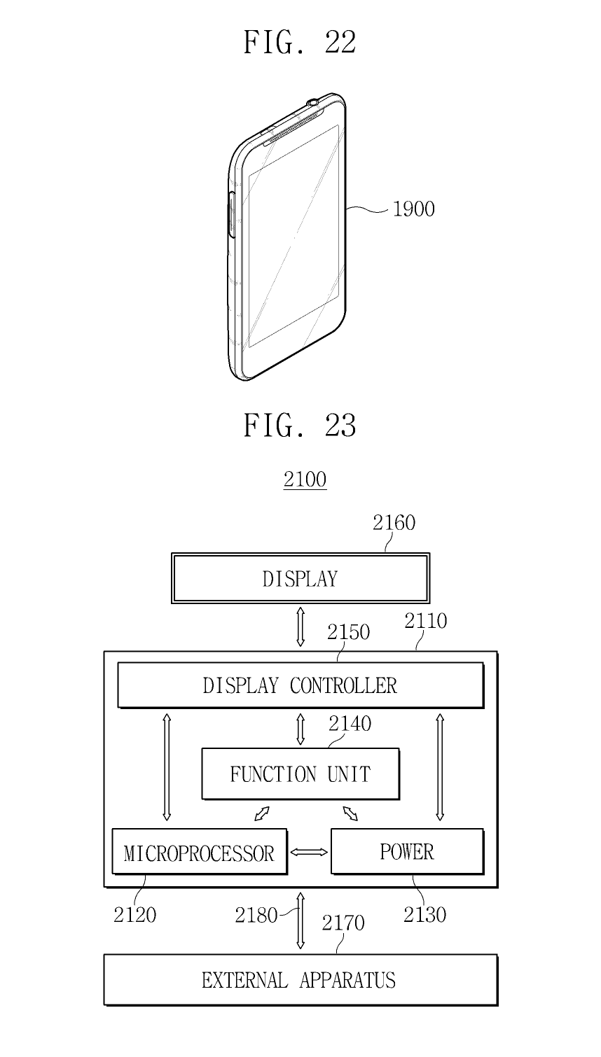

FIGS. 20 to 22 are perspective views of electronic apparatuses in accordance with example embodiments of inventive concepts, and FIG. 23 is a system block diagram of electronic apparatuses in accordance with example embodiments of inventive concepts.

Referring to FIGS. 20 to 22, the semiconductor device described with reference to FIGS. 1 to 17 may be applied to electronic systems such as an embedded multi-media chip (eMMC) 1200, a micro SD 1300, a smart phone 1900, a netbook, a notebook, or a tablet PC. For example, the semiconductor device similar to that described with reference to FIGS. 1 to 17 may be installed on a main board in the smart phone 1900. The semiconductor device similar to that described with reference to FIGS. 1 to 17 may be provided in an expanding apparatus such as the micro SD 1300 and used in the smart phone 1900 configured in combination with the expanding apparatus.

Referring to FIG. 23, the semiconductor device similar to that described with reference to FIGS. 1 to 17 may be applied to an electronic system 2100. The electronic system 2100 may include a body 2110, a microprocessor unit 2120, a power unit 2130, a function unit 2140, and a display controller unit 2150. The body 2110 may be a mother board formed of a printed circuit board (PCB). The microprocessor unit 2120, the power unit 2130, the function unit 2140, and the display controller unit 2150 may be installed on the body 2110. A display unit 2160 may be disposed on the inside or outside of the body 2110. For example, the display unit 2160 may be disposed on the surface of the body 2110 and display an image processed by the display controller unit 2150.

The power unit 2130 configured to have a predetermined power supply from an external battery (not shown), etc. may generate required voltage levels and serve to supply power to the microprocessor unit 2120, the function unit 2140, the display controller unit 2150, etc. The microprocessor unit 2120 may receive power from the power unit 2130 and control the function unit 2140 and the display unit 2160. The function unit 2140 may perform functions of various electronic systems 2100. For example, when the electronic system 2100 is a smart phone, the function unit 2140 may include various configuration elements configured to perform functions of a mobile phone such as displaying an image on the display unit 2160, outputting voice to a speaker, etc. through dialing or communication with an external apparatus 2170, and may serve as a camera image processor when a camera is also installed.

When the electronic system 2100 is connected to a memory card, etc. to expand capacity, the function unit 2140 may be a memory card controller. The function unit 2140 may transmit and receive signals with the external apparatus 2170 through a wired or wireless communication unit 2180. When the electronic system 2100 requires a Universal Serial Bus (USB), etc. to expand functions, the function unit 2140 may serve as an interface controller. The function unit 2140 may include a mass storage apparatus.

The semiconductor device similar to that described with reference to FIGS. 1 to 17 may be applied to the function unit 2140 or the microprocessor unit 2120.

In accordance with example embodiments of inventive concepts, a semiconductor device having repeatedly vertically stacked layers by selectors and resistive change devices can be provided. The selectors formed on an upper layer may have different thicknesses from the selectors formed on a lower layer, and the selectors formed on the upper layer may have different impurity concentrations from the selectors formed on the lower layer. The selectors formed on the upper layer may have substantially the same electrical characteristics as the selectors formed on the lower layer. The semiconductor device can be implemented to use for high integration and to have excellent electrical characteristics.

The foregoing is illustrative of example embodiments and is not to be construed as limiting thereof. Those skilled in the art will readily appreciate that many modifications are possible in example embodiments without materially departing from the novel teachings and advantages. Accordingly, all such modifications are intended to be included within the scope of inventive concepts as defined in the claims. In the claims, means-plus-function clauses are intended to cover the structures described herein as performing the recited function, and not only structural equivalents but also equivalent structures. Therefore, it is to be understood that the foregoing is illustrative of example embodiments and is not to be construed as limited to the specific example embodiments disclosed, and that modifications to the disclosed example embodiments, as well as other example embodiments, are intended to be included within the scope of the appended claims.

What is claimed is:

1. A semiconductor device, comprising:
a first wiring on a substrate;
a second wiring on the first wiring;
a first cell between the first wiring and the second wiring, the first cell having a first selector and a first resistive change device;
a third wiring on the second wiring; and
a second cell between the second wiring and the third wiring, the second cell having a second selector and a second resistive change device, the second selector having a different thickness than the first selector.

2. The semiconductor device according to claim 1, wherein the second selector includes a semiconductor pattern having a different impurity concentration than a semiconductor pattern of the first selector.

3. The semiconductor device according to claim 1, wherein the second selector is thinner than the first selector.

4. The semiconductor device according to claim 1, wherein the first selector includes a first N-type semiconductor pattern and a first P-type semiconductor pattern, and the second selector includes a second N-type semiconductor pattern and a second P-type semiconductor pattern.

5. The semiconductor device according to claim 4, further comprising:
a first intrinsic semiconductor pattern between the first N-type semiconductor pattern and the first P-type semiconductor pattern; and
a second intrinsic semiconductor pattern between the second N-type semiconductor pattern and the second P-type semiconductor pattern.

6. The semiconductor device according to claim 5, wherein the second intrinsic semiconductor pattern is thinner than the first intrinsic semiconductor pattern.

7. The semiconductor device according to claim 6, wherein an impurity concentration of the first N-type semiconductor pattern is higher than an impurity concentration of the second N-type semiconductor pattern.

8. The semiconductor device according to claim 6, wherein an impurity concentration of the first P-type semiconductor pattern is higher than an impurity concentration of the second P-type semiconductor pattern.

9. The semiconductor device according to claim 5, wherein the second intrinsic semiconductor pattern is thicker than the first intrinsic semiconductor pattern.

10. The semiconductor device according to claim 9, wherein the first N-type semiconductor pattern is thicker than the second N-type semiconductor pattern.

11. The semiconductor device according to claim 9, wherein the first P-type semiconductor pattern is thicker than the second P-type semiconductor pattern.

12. The semiconductor device according to claim 9, wherein an impurity concentration of the first N-type semiconductor pattern is higher than an impurity concentration of the second N-type semiconductor pattern.

13. The semiconductor device according to claim 9, wherein an impurity concentration of the first P-type semiconductor pattern is higher than an impurity concentration of the second P-type semiconductor pattern.

14. A semiconductor device, comprising:
a first wiring on a substrate;
a second wiring on the first wiring;
a first cell between the first wiring and the second wiring, the first cell having a first selector and a first resistive change device;
a third wiring on the second wiring; and
a second cell between the second wiring and the third wiring, the second cell having a second selector and a second resistive change device, the second selector having a different impurity concentration than the first selector.

15. The semiconductor device according to claim 14, wherein the first selector includes a first N-type semiconductor pattern and a first P-type semiconductor pattern, and the second selector includes a second N-type semiconductor pattern and a second P-type semiconductor pattern.

16. The semiconductor device according to claim 15, wherein an impurity concentration of the first N-type semiconductor pattern is higher than an impurity concentration of the second N-type semiconductor pattern.

17. The semiconductor device according to claim 15, wherein an impurity concentration of the first P-type semiconductor pattern is higher than an impurity concentration of the second P-type semiconductor pattern.

18. The semiconductor device according to claim 15, further comprising:
a first intrinsic semiconductor pattern between the first N-type semiconductor pattern and the first P-type semiconductor pattern; and
a second intrinsic semiconductor pattern between the second N-type semiconductor pattern and the second P-type semiconductor pattern.

19. A semiconductor device comprising:
a first plurality of wirings;
a second plurality of wirings;
a plurality of first cells between the first plurality of wirings and the second plurality of wirings, the first cells having first selectors and first resistive elements; and
a plurality of second cells on the second plurality of wirings, the second cells having second selectors and second resistive elements, a thickness of the second selectors being less than a thickness of the first selectors.

20. The semiconductor device of claim 26, wherein one first selector forms a PN junction diode.
